(19) United States
(12) Patent Application Publication
(10) Pub. No.: US 2024/0395516 A1
(43) Pub. Date: Nov. 28, 2024

(54) PLASMA STATE VARIABLE SPECIFYING METHOD INCLUDING A DOUBLE PROBE HAVING AN ASYMMETRIC AREA, A PLASMA STATE VARIABLE SPECIFYING APPARATUS INCLUDING A DOUBLE PROBE HAVING AN ASYMMETRIC AREA, AND A PLASMA GENERATING APPARATUS INCLUDING THE SAME

(71) Applicant: IUCF-HYU(INDUSTRY-UNIVERSITY COOPERATION FOUNDATION HANYANG UNIVERSITY), Seoul (KR)

(72) Inventors: Chin Wook CHUNG, Seoul (KR); Hyun Dong EO, Seoul (KR)

(73) Assignee: IUCF-HYU(INDUSTRY-UNIVERSITY COOPERATION FOUNDATION HANYANG UNIVERSITY), Seoul (KR)

(21) Appl. No.: 18/690,811

(22) PCT Filed: Sep. 8, 2022
(86) PCT No.: PCT/KR2022/013550

§ 371 Date: May 23, 2024

(30) Foreign Application Priority Data
Sep. 10, 2021 (KR) 10-2021-0121297

(51) Int. Cl. H01J 37/32; G01R 19/00

(52) U.S. Cl. CPC H01J 37/32917; G01R 19/0092; H01J 2237/24564

(57) ABSTRACT

A device measuring plasma state variable including a dual probe with asymmetric area according to an embodiment may comprise a first probe and a second probe, a voltage applicator that applies a preset voltage to the first probe and the second probe, a current measuring part that measures current flowing through the first probe and the second probe and a plasma analysis part that calculates the electron temperature and density of the plasma inside a chamber based on the results measured by the current measuring part, and wherein the area of the first probe and the area of the second probe are different sizes.

### TECHNICAL FIELD

The present invention relates to a method for specifying a plasma state variable including a dual probe having an asymmetric area, a device for specifying a plasma state variable including a dual probe having an asymmetric area, and a plasma generation device including the same. And more specifically, the invention relates to a technology for measuring the temperature and density of plasma more accurately than the prior art based on the current value flowing through the probes by varying the areas of the two probes that measure the density and the temperature of the plasma.

### BACKGROUND ART

Plasma is an ionized gas, which is composed of positive ions, negative ions, electrons, excited atoms, molecules, and chemically very active radicals. It has electrically and thermally very different properties from ordinary gases, so it is a material called the fourth state. This plasma contains ionized gas and is very useful in the semiconductor manufacturing process, such as accelerating it using an electric or magnetic field or causing a chemical reaction to clean, etch, or deposit a wafer or substrate.

Recently, in the semiconductor manufacturing process, plasma generators that generate high-density plasma have been used, and there are several plasma modules for generating plasma, including capacitive coupled plasma (CCP) using radio frequency. Representative examples include inductively coupled plasma (ICP).

Capacitively coupled plasma modules have the advantage of higher process productivity compared to other plasma modules due to their accurate capacitive coupling control and high ion control ability. On the other hand, because the energy of the radio frequency power source is coupled to the plasma almost exclusively through capacitive coupling, the plasma ion density can only be increased or decreased by increasing or decreasing the capacitively coupled radio frequency power. However, increasing radio frequency power increases ion bombardment energy. As a result, there are limitations to radio frequency power to prevent damage from ion bombardment.

Meanwhile, inductively coupled plasma modules can easily increase ion density as radio frequency power increases, and the resulting ion bombardment is relatively low, making it suitable for obtaining high-density plasma. Therefore, inductively coupled plasma modules are commonly used to obtain high-density plasma. Inductively coupled plasma modules are typically developed using a radio frequency antenna (RF antenna) and a transformer method (also known as transformer coupled plasma).

In plasma generation devices, plasma density or electron temperature plays an important role in the results of semiconductor and display processes, so accurately measuring plasma density or electron temperature is an essential field in research utilizing plasma. In general, a probe is inserted into the chamber, the density and electron temperature of the plasma are measured based on the current flowing through the probe, and a representative technology is a technology that analyzes harmonic components flowing through the probe near the floating potential.

However, when analyzing harmonic components according to the prior art, the second harmonic current cannot be measured due to the nature of the probe having a symmetrical structure, so the ratio of the first harmonic current and the third harmonic current corresponding to the fundamental frequency is used for measuring the density of plasma and the temperature of electrons. However, since the third harmonic current was measured at a much smaller scale than the first harmonic current, there was a disadvantage in that it was difficult to accurately measure the density of the plasma and the temperature of the electrons. Accordingly, in an environment where low-density plasma exists, a probe with a relatively large area was required, and there was a problem in that a wide range of current had to be measured for accurate calculations.

### DISCLOSURE

### Technical Problem

Therefore, a method for specifying a plasma state variable including a dual probe with an asymmetric area, a device for specifying a plasma state variable including a dual probe with an asymmetric area, and a plasma generation device including the same according to an embodiment can solve the problems described above. The purpose of this invention is to provide a device and method that can measure the density and electron temperature of plasma more accurately than the prior art by using the first and second harmonic currents, which are easy to measure in terms of state.

More specifically, a method for specifying a plasma state variable including a dual probe having an asymmetric area, a device for specifying a plasma state variable including a dual probe having an asymmetric area, and a plasma generation device including the same has a purpose to provide a method and device for measuring plasma state variable measuring the first harmonic current and the second harmonic current by varying the areas of the first and second probes inside a chamber and measuring the density and electron temperature of the plasma based on the measured values.

### Technical Solution

A device measuring plasma state variable including a dual probe with asymmetric area according to an embodiment may comprise a first probe and a second probe, a voltage applicator that applies a preset voltage to the first probe and the second probe, a current measuring part that measures current flowing through the first probe and the second probe and a plasma analysis part that calculates the electron temperature and density of the plasma inside a chamber based on the results measured by the current measuring part, and wherein the area of the first probe and the area of the second probe are different sizes.
wherein the shapes of the first probe and the second probe are same shape, and wherein the area of the first probe is larger than that of the second probe.
wherein the shapes of the first probe and the second probe are a cuboid-shaped probe or a cylindrical-shaped probe.
wherein the horizontal length of the first probe and the second probe are the same, but the vertical length of the first probe is greater than the vertical length of the second probe.
wherein the area of the first probe is 2 to 5 times the area of the second probe.
wherein the first probe and the second probe are respectively connected to both ends of the voltage applicator.
wherein the voltage applicator applies a sinusoidal voltage to the first probe and the second probe.
wherein the plasma analysis part calculates the electron temperature and density of the plasma using the relationship between the measured value of the current and area ratio information for the second probe based on the first probe, area information of the first probe, density information of the current, and information on the magnitude of the voltage.
wherein the plasma analysis part calculates the electron temperature and density of plasma using the relative size information of the fundamental frequency current and the harmonic frequency current after classifying the measured current as the sum of the fundamental frequency current and harmonic frequency currents having a frequency that is an integer multiple of the frequency of the fundamental frequency current.
wherein the plasma analysis part calculates the electron temperature and density of the plasma using the ratio of the fundamental frequency current and the second harmonic frequency current.

A device generating plasma including a plurality of probes with asymmetric areas according to an embodiment may comprise a chamber in which plasma is generated, a plurality of probes disposed inside the chamber, a voltage applicator that applies a preset voltage to the plurality of probes, a current measuring part that measures current flowing through the plurality of probes and a plasma analysis part that calculates the electron temperature and density of the plasma inside the chamber based on the results measured by the current measuring part, and wherein the plurality of probes each have an area of different size.

A method of measuring plasma state variable using a dual probe with asymmetric area according to an embodiment may comprises a voltage application step of applying a preset voltage to a first probe and a second probe having different areas each and disposed inside a chamber, a current measuring step of measuring current flowing through the first probe and the second probe and a plasma analysis step of calculating the electron temperature and density of the plasma inside the chamber based on the results measured in the current measuring step.
wherein the first probe and the second probe have the same shape and the area of the first probe is larger than that the area of the second probe.
wherein the plasma analysis step includes a step of calculating the electron temperature and density of the plasma using the relationship between the measured value of the current and area ratio information for the second probe based on the first probe, area information of the first probe, density information of the current, and information on the magnitude of the voltage.
wherein the plasma analysis step includes a step of calculating the electron temperature and density of plasma using the relative size information of the fundamental frequency current and the harmonic frequency current after classifying the measured current as the sum of the fundamental frequency current and harmonic frequency currents having a frequency that is an integer multiple of the frequency of the fundamental frequency current.

### Advantageous Effects

According to an embodiment, a method for specifying a plasma state variable including a dual probe with an asymmetric area, a device for specifying a plasma state variable including a dual probe with an asymmetric area, and a plasma generation device including the same can measure the density of plasma and the temperature of electrons by using a first harmonic current and a second harmonic current. So, there is an advantage in measuring the density of plasma and the temperature of electrons more accurately than when measuring using the third harmonic current according to the prior art.

In addition, due to these advantages, the plasma density and electron temperature can be measured with a relatively small probe, making it possible to implement a relatively small plasma variable measurement device, and the current measurement range can be made smaller than the conventional technology. So, there is an effect that making it more efficiently to measure the density and electron temperature of plasma.

The effects of the present invention are not limited to the technical problems mentioned above, and other effects not mentioned will be clearly understood by those skilled in the art from the description below.

### BRIEF DESCRIPTION OF DRAWINGS

To more fully understand the drawings cited in the detailed description of the present invention, a brief description of each drawing is provided.

FIG. 1 is a block diagram showing some components of a plasma generation device according to an embodiment of the present invention.

FIG. 2 is a perspective view of the plasma generation device according to an embodiment of the present invention when viewed from the side.

FIG. 3 is a diagram showing various shapes that the first probe and the second probe may have according to an embodiment of the present invention.

FIG. 4 shows a graph of the electron temperature measured according to the change in the size of the power source when the areas of the first probe and the second probe are the same and when the area of the first probe is twice and three times of the area of the second probe.

FIG. 5 is a block diagram showing some components of a plasma state variable measuring device including a dual probe with an asymmetric area corresponding to another embodiment of the present invention.

FIG. 6 is a diagram illustrating a case where a plasma state variable measuring device including a dual probe having an asymmetric area according to the present invention is combined with a plasma generation device in a wired form.

FIG. 7 is a diagram illustrating a case where a plasma state variable measuring device including a dual probe having an asymmetric area according to the present invention is wirelessly coupled to a plasma generating device.

### MODES OF THE INVENTION

Hereinafter, embodiments according to the present invention will be described with reference to the attached drawings. When adding reference signs to components in each drawing, it should be noted that the same components are given the same reference numerals as much as possible even if they are shown in different drawings. Additionally, when describing embodiments of the present invention, if detailed descriptions of related known configurations or functions are judged to impede understanding of the embodiments of the present invention, the detailed descriptions will be omitted. In addition, embodiments of the present invention will be described below, but the technical idea of the present invention is not limited or limited thereto and may be modified and implemented in various ways by those skilled in the art.

Additionally, the terms used in this specification are used to describe embodiments and are not intended to limit and/or limit the disclosed invention. Singular expressions include plural expressions unless the context clearly dictates otherwise.

In this specification, terms such as “comprise,” “provide,” or “have” intended to designate the presence of features, numbers, steps, operations, components, parts, or combinations thereof described in the specification. It does not exclude in advance the existence or addition of other features, numbers, steps, operations, components, parts, or combinations thereof.

In addition, throughout the specification, when a part is said to be “connected” to another part, this refers not only to the case where it is “directly connected” but also to the case where it is “indirectly connected” with another element in between. Terms including ordinal numbers, such as “first” and “second,” used in this specification may be used to describe various components, but the components are not limited by the terms.

Below, with reference to the attached drawings, embodiments of the present invention will be described in detail so that those skilled in the art can easily implement the present invention. To clearly explain the present invention in the drawings, parts unrelated to the description are omitted.

Meanwhile, the name of the present invention was described as ‘a plasma generation device including a dual probe with an asymmetric area’, but for convenience of explanation below, ‘a plasma generation device including a dual probe with an asymmetric area’ is referred to as ‘a plasma generating device’ to explain.

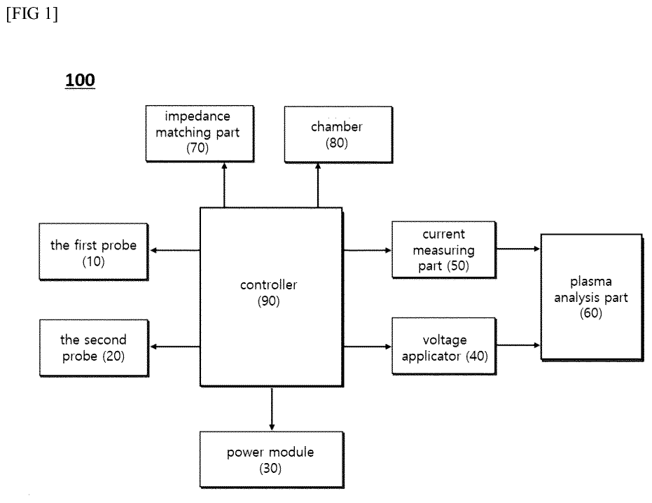

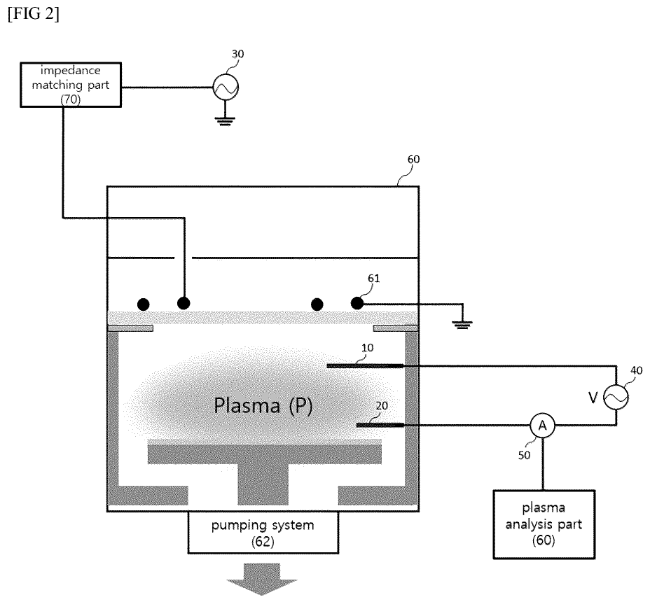

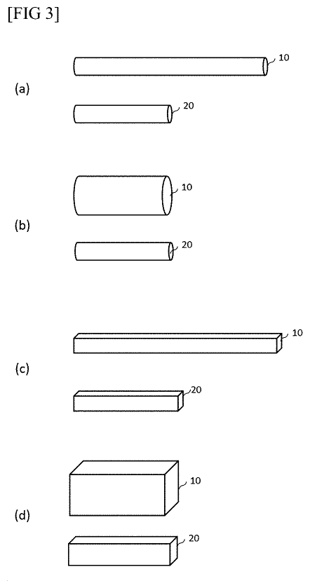

FIG. 1 is a block diagram showing some components of a plasma generation device according to an embodiment of the present invention, FIG. 2 is a perspective view of the plasma generation device according to an embodiment of the present invention when viewed from the side, and FIG. 3 is a diagram showing various shapes that the first and second probes may have according to an embodiment of the present invention.

Referring to FIGS. 1 to 3, the plasma generation device 100 according to the present invention includes a first probe 10, a second probe 20 that are disposed in a chamber and can measure various variables of plasma, a power module 30 that supplies power to the plasma generation device 100, a voltage applicator 40 that applies a preset voltage to the first probe 10 and the second probe 20, a current measuring part 50 that measures the current flowing in the first probe 10, and the second probe 10, a plasma analysis part 60 that calculates various variables of the plasma based on the results measured by the current measuring part 50, an impedance matching part 70 matching impedance of an antenna 61, and a chamber 80 that serves as a main body and generates plasma.

Referring to FIG. 2, the chamber 80 may refer to a container having a space where an object requiring plasma processing, such as a substrate, is provided, and a space where plasma P is generated. As shown in FIG. 2, a plurality of antennas 61 for generating plasma may be installed on the upper part of the chamber 80, and the plurality of antennas 61 may be connected to an impedance matching part 70 (matching box). The impedance matching part 70 may be connected to the power module 30 and the chamber 80 that supply power to the plasma generation device 100, respectively.

A pumping system 62 may be formed in the lower part of the chamber 80 to pump a source gas that is a source of plasma.

As shown in FIG. 1, a method of generating plasma using a plurality of antennas 61 may be referred to as an inductively coupled plasma generating device. However, the plasma generation device and method of measuring plasma variables using the same according to the present invention can be applied not only to the device and method for generating plasma using the inductive coupling method, but also to the device and method for generating plasma using the capacitive coupling method. For convenience of explanation, the description will be made based on the inductively coupled plasma generation device shown in FIG. 2.

The plasma generation device 100 according to an embodiment of the present invention can measure various variables of plasma generated inside the chamber 80. The variable referred to in the present invention refers to a variable that refers to various chemical and physical characteristics related to plasma. As a representative example of the plasma generation device 100 according to the present invention, the plasma generation device 100 can measure the density of the plasma, the temperature of electrons flowing inside the chamber, and the probability distribution of electron energy inside the chamber 80.

For this purpose, a plurality of probes may be provided inside the chamber 80. In a representative embodiment, a first probe 10 and a second probe 20 capable of transmitting a sinusoidal wave to plasma may be provided. The probe 10 and the second probe 20 may be arranged to penetrate one wall of the chamber 80 as shown in the drawing. As shown in FIG. 2, when the first probe 10 and the second probe 20 penetrate the chamber 80 and apply a sinusoidal signal to the plasma, the first probe 10 and the second probe 20 can be said to have the form of a floating probe.

The voltage applicator 40 generates a voltage and then applies the generated voltage to the first probe 10 and the second probe 20. As shown in FIG. 2, the voltage applicator 40 is electrically connected to the first probe 10 and the second probe 20, and the user's signal is applied to the first probe 10 and the second probe 20. Therefore, a preset voltage can be applied according to the settings. The shape and size of the voltage applied to the first probe 10 and the second probe 20 by the voltage applicator 40 may be set differently depending on the plasma generation environment, but in the form of a sinusoidal wave generated by alternating voltage can be applied.

Meanwhile, although not shown in FIG. 2, a self-bias generator (not shown) may be disposed between the first probe 10 and the second probe 20 and the source of the voltage applicator 40. When the sinusoidal signal generated by the voltage applicator 40 passes through the self-bias generator, a self-bias voltage is applied to both ends of the self-bias generator. The self-bias or self-bias voltage value applied to the self-bias generator can be measured in the plasma analysis part 60. Here, a resistor (not shown) may be connected between the self-bias generator and the voltage applicator 40 so that the self-bias generator can efficiently generate self-bias.

The first probe 10 and the second probe 20 are disposed inside the chamber 80 as shown in FIG. 2 and may be made of a metal probe to allow current to flow. When voltage is applied to the first probe 10 and the second probe 20 by the voltage applicator 40, the potential difference between the plasma and the first probe 10 and the second probe 20 causes the current flowing through the first probe 10 and the second probe 20, so the current measuring part 50 can measure the current flowing through the first probe 10 and the second probe 20. In FIG. 2, the current measuring part 50 is shown as being disposed between the second probe 20 and the voltage applying unit 40. However, in another embodiment of the present invention, the current measuring part 50 is connected to the first probe 10 and the voltage applicator 40.

The first probe 10 and the second probe 20 according to the present invention may have different shapes or may be composed of probes having the same shape but different areas.

For example, the first probe 10 and the second probe 20 according to the present invention are implemented as cylindrical probes as shown in (a) and (b) of FIG. 3, or it can be implemented as a probe in the shape of a rectangular parallelepiped as shown in (c) and (d) of FIG. 3. However, embodiments of the present invention are not limited to cylindrical probes or rectangular parallelepiped probes and may be implemented as probes of various shapes if they are capable of measuring the density of plasma or the temperature of electrons.

In addition, according to the present invention, the first probe 10 and the second probe 20 disposed inside the chamber 80 may be implemented to have different areas, and specifically, the area of the first probe 10 can be implemented with an area larger than that of the second probe 20.

That is, when the first probe 10 and the second probe 20 are implemented as cylindrical probes, the vertical length of the first probe 10 and the second probe 20 is the same, but the horizontal length of the first probe 10 is longer, so that the area of the first probe 10 is larger than the area of the second probe 20 as shown in (a) of FIG. 3.

In addition, as shown in (b) of FIG. 3, the horizontal length of the first probe 10 and the second probe 20 are the same, but the vertical length of the first probe 10 is longer, so that the area of the first probe 10 may be larger than the area of the second probe 20. In one embodiment, the area of the first probe 10 may be 2 to 10 times to the area of the second probe 20.

In addition, when the first probe 10 and the second probe 20 are implemented as rectangular parallelepiped-shaped probes, as shown in (c) of FIG. 3, the vertical length of the first probe 10 and the second probe 20 is the same, but the horizontal length of the first probe 10 is longer, so that the area of the first probe 10 is larger than the area of the second probe 20.

In addition, as shown in (d) of FIG. 3, the horizontal length of the first probe 10 and the second probe 20 are the same, but the vertical length of the first probe 10 is longer, so that the area of the probe 10 may be larger than the area of the second probe 20. In one embodiment, the area of the first probe 10 may be 2 to 10 times to the area of the second probe 20.

The controller 90 can control various components of the plasma generation device 100. Specifically, the controller 90 controls the power module 30 that applies voltage to the plasma generation device 100, and can control the size or model of the voltage applied to the plasma generation device 100, impedance, etc. By adjusting the size of the impedance of impedance matching part 70, the amount or density of plasma generated by the plasma generation device 100 can be adjusted by the controller 90.

In addition, the controller 90 controls the voltage applicator 40 that applies voltage to the first probe 10 and the second probe 20. So, the voltage size and frequency of the sine plate applied to the first probe 10 and the second probe 20 can be controlled.

Accordingly, the controller 90 may include a processor, a controller, an arithmetic logic unit (ALU), a digital signal processor, a microcomputer, a field programmable array (FPA), a programmable logic unit (PLU), a microprocessor, or an instruction. And it can be implemented as a device that can execute and respond to instructions.

In addition, although the drawing shows the configuration of the controller 90 and the plasma analysis part 60, which will be described later, as separate components, the embodiment of the present invention is not limited to this, and the controller 90 and the plasma analysis part 60 can also be implemented as a single element as a single component.

The plasma analyzer 60 may calculate the electron temperature and density of the plasma inside the chamber based on the results measured by the current measuring part 50.

f the areas of the first probe and the second probe are the same, the ion saturation currents of the first probe and the second probe are the same. Therefore, the current (I) measured by the current measuring part 50 can be expressed by the following equation (1).

$$I = \frac{I + {I}_{1 i}}{{I}_{2 i} - I} = \frac{{A}_{1}}{{A}_{2}} e \text{?} \qquad Equation ( 1 )$$

$$\text{?} \text{indicates text missing or illegible when filed}$$

In equation (1), I₁ᵢ and I₁₂ represent the ion saturation current flowing through the first and second probes, V represents the magnitude of the voltage applied to the first and second probes, and Te represents the temperature of the electrons. If the ion saturation current flowing in the first probe is the same as the ion saturation current flowing in the second probe, and the area A1 of the first probe is the same as the area A2 of the second probe, Equation (1) can be summarized as equation (2) as follows.

$$I = \frac{I + {I}_{i}}{{I}_{i} - I} = e \text{?} = {I}_{i} tanh ( \frac{T \text{?}}{2 V} ) \qquad Equation ( 2 )$$

$$\text{?} \text{indicates text missing or illegible when filed}$$

And since the voltage applied to the first probe 10 and the second probe 20 is a regular voltage, the above equation (2) can be summarized using De Moivre's formula, the equation can be separated into the sum of each odd harmonic as follows.

$$I / {I}_{i} = ( a - \frac{{a}^{3}}{4} + \frac{{a}^{5}}{12} + … ) cos ω t + ( - \frac{{a}^{3}}{12} + \frac{{a}^{5}}{24} + … ) cos 3 ω t + ( \frac{{a}^{5}}{120} + … ) cos 5 ω t + … , ( a = {V}_{0} / 2 T \text{?} ) \qquad Equation ( 3 )$$

$$\text{?} \text{indicates text missing or illegible when filed}$$

That is, if the areas of the first probe 10 and the second probe 20 are the same, the even high-frequency components are canceled out and deleted from the current measured by the current measuring part 50 because the saturated ion current is the same, and It is expressed only as the sum of harmonics of the odd high-frequency components.

Therefore, the density of plasma and the temperature of electrons can be measured using the first harmonic current and the third harmonic current, which have the largest current magnitude among the separated harmonics. However, when measuring the density of plasma or the temperature of electrons using this method, there is a disadvantage that the density of the plasma cannot be accurately measured in low-density plasma because the third harmonic current is measured to be much smaller than the first harmonic current. Therefore, in a low-density plasma environment, there are problems that not only require a probe with a relatively large area, but also require a wide current measurement range.

Therefore, the plasma generation device 100 according to an embodiment of the present invention measures the density of plasma and the temperature of electrons more accurately than the prior art by varying the areas of the first probe 10 and the second probe 20. Specifically, when analyzing the current measured by the current measuring part 50, the plasma generation device 100 leaves even high-frequency components, so that the first harmonic current and the second harmonic current can be more easily measured. And using this information, the density of plasma and the temperature of electrons can be measured. Let's look at it in detail below.

If the areas of the first probe 10 and the second probe 20 are not the same, the current flowing in the current measuring part 50 can be expressed using current density, specifically it can be expressed as equation (4) below.

$$\frac{I + α {AJ}_{i}}{{AJ}_{i} - I} = α {e}^{x} , ( x = V / {T}_{e} ) \qquad Equation ( 4 )$$

And if equation (4) is organized based on the current I, it can be expressed as equation (5) below.

$$I = α {AJ}_{i} \frac{( {e}^{x} - 1 )}{( 1 + α {e}^{x} )} \qquad Equation ( 5 )$$

In equation (5), α means the area ratio of the first probe 10 and the second probe 20 based on the area of the first probe 10, A is the area of the first probe 10, and Ji is the ion current density, V, refers to the amplitude of the voltage applied to the first probe 10 and the second probe 20.

And if equation (5) is rearranged using Taylor series, it can be expressed as equation (6) below.

$$I = α {A}_{2} {J}_{i} \frac{( {e}^{x} - 1 )}{( 1 + α {e}^{x} )} \approx α {A}_{2} {J}_{i} ( \frac{1}{α + 1} x - \frac{1}{2} \frac{α - 1}{{( α + 1 )}^{2}} {x}^{2} + … ) \qquad Equation ( 6 )$$

And if the applied voltage in equation (6) above is set to cos(x), the equation can be summarized as equation (7) below.

$$I ( υcos x ) \approx α {A}_{2} {J}_{i} ( \frac{1}{α + 1} ( υ cos x ) - \frac{1}{2} \frac{α - 1}{{( α + 1 )}^{2}} {( υ cos x )}^{2} + … ) \qquad Equation ( 7 )$$

And the above equation (7) can be summarized as the sum of the fundamental frequency current and the harmonic current using the cosine double angle formula, and in this case, information about the fundamental frequency and the second harmonic current can be obtained. Therefore, the electron temperature can be obtained by using the ratio of the fundamental frequency current and the second harmonic current component, and the ion density can be summarized as a function of the fundamental frequency current and the electron temperature. For example, if the area ratio of the first probe 10 and second probe 20 is 1:2, the electron temperature and ion density can be obtained by organizing equations (8) and (9) below.

$${T}_{e} \approx \frac{{υ}_{0}}{12} \frac{{I}_{a 1}}{{I}_{a 2}} , \qquad Equation ( 8 )$$

$${n}_{i} \approx \frac{{I}_{1 w}}{1.83 eu \text{?} A} \frac{{T}_{e}}{{υ}_{0}} \qquad Equation ( 9 )$$

$$\text{?} \text{indicates text missing or illegible when filed}$$

In equations (7) and (8), Vo means the amplitude of the voltage applied to the first probe 10 and the second probe 20, I_{1w} means the fundamental frequency current, e means the amount of charge, and U_{b} means the bohm diffusion rate. In other words, since the present invention measures the density of plasma and the temperature of electrons through this method, it can be measured more accurately than the prior art.

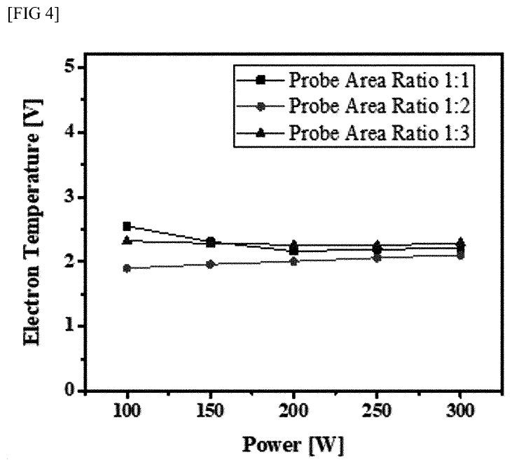

FIG. 4 shows a graph of the electron temperature measured according to the change in the size of the power source when the areas of the first probe and the second probe are the same, and when the area of the first probe is twice and three times the area of the second probe.

Referring to FIG. 4, when the areas of the first and second probes are the same (area ratio is 1:1), the measured value of the third harmonic current is small, so the measured electronic temperature value also changes as the size of the power changes. Therefore, in order to obtain accurate measurement values in such an environment, a probe with an area approximately 10 times larger than that of a typical probe must be used.

In addition, when the areas of the probes are the same, as shown in FIG. 4, the results show a different tendency from the results measured when the areas of the probes are not the same as the power level increases from 200W to 100W. This phenomenon refers to the result of errors that occur as the measurement becomes inaccurate as the ion density decreases and the third harmonic current decreases.

However, as shown in FIG. 4, when using the second harmonic current, there is no significant difference in the temperature of the measured electrons even if the power of the applied voltage changes. This shows that reliable electron temperatures can be obtained even with a relatively smaller area than probes with the same area.

In addition, in the case of a symmetrical dual probe where the probes have the same area, it is difficult to accurately measure the temperature of electrons because the ratio of the first harmonic current to the third harmonic current is 200 to 1000 times greater. However, according to the present invention, in the case of an asymmetric dual probe implemented by varying the area of first probe 10 and the second probe 20, the ratio of the current between the first harmonic and the second harmonic is measured to be about 20 to 50 times smaller than that of the symmetrical dual probe. Therefore, from this point, when a device for measuring the state variable of plasma is implemented as a wireless diagnostic device, the magnitude of the voltage for measurement can be reduced compared to when using an asymmetrical dual probe at the same electron temperature, thereby reducing the plasma state variable. So, there is an advantage to making the measuring device smaller.

Meanwhile, in FIGS. 1 to 3, for convenience of explanation, the description is based on the plasma generation device 100, which is one of several embodiments of the present invention. However, the present invention can be implemented as a plasma state variable measuring device 200 including a dual probe with an asymmetric area. Let's look at the drawings below in detail.

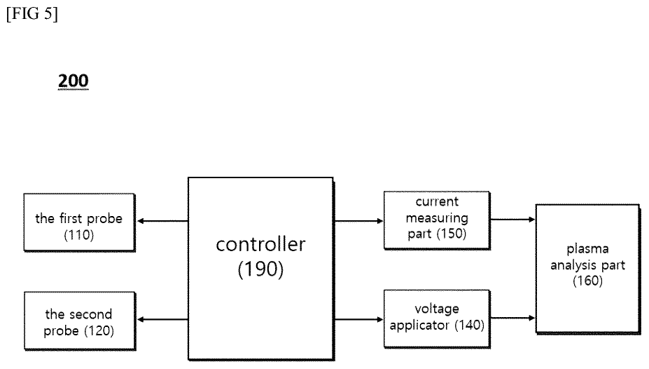

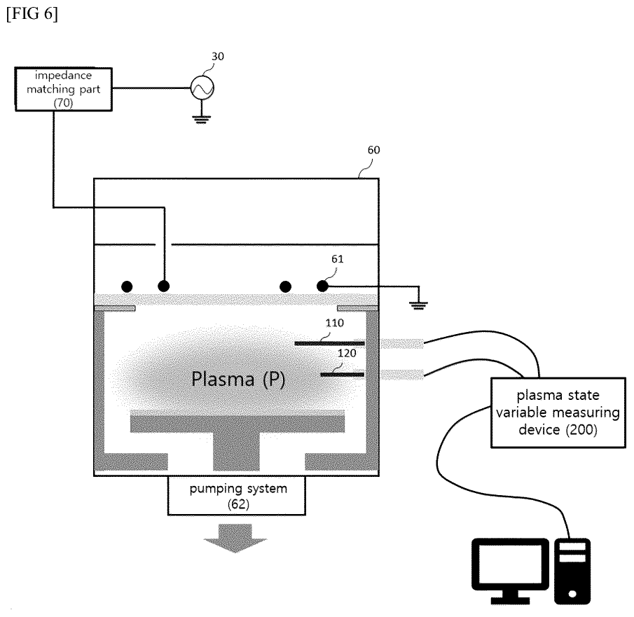

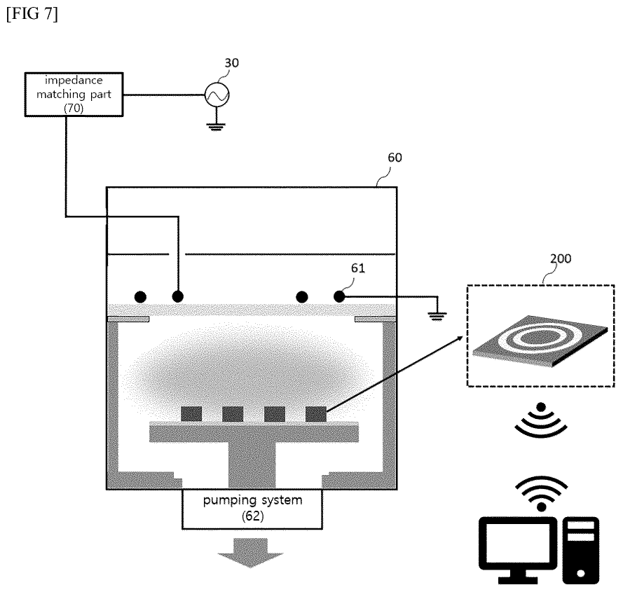

FIG. 5 is a block diagram showing some components of a plasma state variable measuring device including a dual probe with an asymmetric area corresponding to another embodiment of the present invention, FIG. 6 is a diagram illustrating a case where a plasma state variable measuring device including a dual probe having an asymmetric area according to the present invention is combined with a plasma generation device in a wired form, and FIG. 7 is a diagram illustrating a case where a plasma state variable measuring device including a dual probe having an asymmetric area according to the present invention is wirelessly coupled to a plasma generating device. For convenience of explanation, the ‘plasma state variable measuring device including a dual probe with an asymmetric area’ will be referred to as the ‘plasma state variable measuring device’.

Referring to FIG. 5, the state variable measuring device 200 can include a first probe 110, and the second probe 120, a voltage applicator 140 applying a preset voltage to the first probe 110 and the second probe 120, a current measuring part 150 which measures the current flowing through the voltage applicator 140, a plasma analysis part 160 calculating various variables of the plasma based on the results measured by the current measuring part 150, and a controller 190 that controls overall components of the plasma state variable measurement device 200 including a dual probe with an asymmetric area. And as shown in FIG. 5, the first probe 110, the second probe 120, the power module 130, the voltage applicator 140, the current measuring part 150, the plasma analysis part 160, and the controller 190 have the same function as the first probe 10, the second probe 20, the power module 30, the voltage applicator 40, the current measuring part 50, the plasma analysis part 60, and the controller 90 as described in FIG. 2. So, redundant explanations should be omitted.

The plasma state variable measuring device 200 including a dual probe with an asymmetric area according to FIG. 5 is a device implemented separately from the plasma generation device 100. Due to its nature, it is connected to the plasma generation device 100 to generate plasma inside the chamber and measuring the density of the plasma and electron temperature.

Therefore, as shown in FIG. 6, the plasma state variable measuring device 200 is connected to the plasma generation device 100 by a wired method and measuring various state variables of the plasma generated inside the chamber of the plasma generation device. And as shown in FIG. 7, it is connected to the plasma generation device in a combined manner, and various state variables of the plasma generated inside the chamber of the plasma generation device can be measured. When the plasma state variable measuring device 200 is connected to the plasma generation device in the method shown in FIG. 7, the plasma state variable measuring device 200 can be disposed plurally including a battery, a measurement circuit, and a first probe and a second probe in the chamber as shown in the figure above the pumping system 62. And each plurality of plasma state variable measuring devices includes a communication module capable of communicating with an external terminal or external server, so that it can operate independently inside the chamber. The operating principle of the plasma state variable measuring device 200 according to FIG. 7 is the same as previously described and will be omitted.

Through the drawings so far, a plasma state variable specification method including a dual probe with an asymmetric area, a plasma state variable specification device including a dual probe with an asymmetric area, and components for a plasma generation device including the same according to an embodiment investigated details about how it works.

A method for specifying a plasma state variable including a dual probe with an asymmetric area, a device for specifying a plasma state variable including a dual probe with an asymmetric area, and a plasma generation device including the same according to an embodiment can measure the density of plasma and the temperature of electrons using a first harmonic current and a second harmonic current. So, there is an advantage in measuring the density of plasma and the temperature of electrons more accurately than when measuring using the third harmonic current according to the prior art.

In addition, due to these advantages, the plasma density and electron temperature can be measured with a relatively small probe, making it possible to implement a relatively small plasma variable measurement device, and the current measurement range can be made smaller than the conventional technology, there is an effect that can measure the density and electron temperature of plasma more efficiently.

The device described above may be implemented with hardware components, software components, and/or a combination of hardware components and software components. For example, devices and components described in embodiments may include, for example, a processor, a controller, an arithmetic logic unit (ALU), a digital signal processor, a microcomputer, a field programmable array (FPA). It may be implemented using one or more general-purpose or special-purpose computers, such as a programmable logic unit (PLU), microprocessor, or any other device capable of executing and responding to instructions. A processing device may perform an operating system (OS) and one or more software applications that run on the operating system. Additionally, a processing device may access, store, manipulate, process, and generate data in response to the execution of software. For case of understanding, a single processing device may be used; however, those skilled in the art will understand that a processing device includes multiple processing elements and/or multiple types of processing elements. For example, a processing device may include multiple processors or one processor and one controller. Additionally, other processing configurations, such as parallel processors, are possible.

Software may include a computer program, code, instructions, or a combination of one or more of these, which may configure a processing unit to operate as desired or may be processed independently or collectively. Software and/or data may be used on any type of machine, component, physical device, virtual equipment, computer storage medium or device to be interpreted by or to provide instructions or data to a processing device. Software may be distributed over networked computer systems and stored or executed in a distributed manner. Software and data may be stored on one or more computer-readable recording media.

The method according to the embodiment may be implemented in the form of program instructions that can be executed through various computer means and recorded on a computer-readable medium. The computer-readable medium may include program instructions, data files, data structures, etc., singly or in combination. Program instructions recorded on the medium may be specially designed and configured for the embodiment or may be known and available to those skilled in the art of computer software. Examples of computer-readable recording media include magnetic media such as hard disks, floppy disks, and magnetic tapes, optical media such as CD-ROMs and DVDs, and magnetic media such as floptical disks.—Includes optical media (magneto-optical media) and hardware devices specifically configured to store and execute program instructions, such as ROM, RAM, flash memory, etc. Examples of program instructions include machine language code, such as that produced by a compiler, as well as high-level language code that can be executed by a computer using an interpreter, etc.

As described above, although the embodiments have been described with limited examples and drawings, various modifications and variations can be made by those skilled in the art from the above description. For example, the described techniques are performed in a different order than the described method, and/or components of the described system, structure, device, circuit, etc. are combined or combined in a different form than the described method, or other components are used. Alternatively, appropriate results may be achieved even if substituted or substituted by an equivalent. Therefore, other implementations, other embodiments, and equivalents of the claims also fall within the scope of the claims described below.

1. A device measuring plasma state variable including a dual probe with asymmetric area comprising:
a first probe and a second probe;
a voltage applicator that applies a preset voltage to the first probe and the second probe;
a current measuring part that measures current flowing through the first probe and the second probe;
a plasma analysis part that calculates the electron temperature and density of the plasma inside a chamber based on the results measured by the current measuring part; and
wherein the area of the first probe and the area of the second probe are different sizes.

2. The device measuring plasma state variable including a dual probe with asymmetric area according to claim 1,
wherein the shapes of the first probe and the second probe are same shape, and
wherein the area of the first probe is larger than that of the second probe.

3. The device measuring plasma state variable including a dual probe with asymmetric area according to claim 1,
wherein the shapes of the first probe and the second probe are a cuboid-shaped probe or a cylindrical-shaped probe.

4. The device measuring plasma state variable including a dual probe with asymmetric area according to claim 3,
wherein the horizontal length of the first probe and the second probe are the same, but the vertical length of the first probe is greater than the vertical length of the second probe.

5. The device measuring plasma state variable including a dual probe with asymmetric area according to claim 2,
wherein the area of the first probe is 2 to 5 times the area of the second probe.

6. The device measuring plasma state variable including a dual probe with asymmetric area according to claim 1,
wherein the first probe and the second probe are respectively connected to both ends of the voltage applicator.

7. The device measuring plasma state variable including a dual probe with asymmetric area according to claim 6,
wherein the voltage applicator applies a sinusoidal voltage to the first probe and the second probe.

8. The device measuring plasma state variable including a dual probe with asymmetric area according to claim 5,
wherein the plasma analysis part calculates the electron temperature and density of the plasma using the relationship between the measured value of the current and area ratio information for the second probe based on the first probe, area information of the first probe, density information of the current, and information on the magnitude of the voltage.

9. The device measuring plasma state variable including a dual probe with asymmetric area according to claim 5,
wherein the plasma analysis part calculates the electron temperature and density of plasma using the relative size information of the fundamental frequency current and the harmonic frequency current after classifying the measured current as the sum of the fundamental frequency current and harmonic frequency currents having a frequency that is an integer multiple of the frequency of the fundamental frequency current.

10. The device measuring plasma state variable including a dual probe with asymmetric area according to claim 9,
wherein the plasma analysis part calculates the electron temperature and density of the plasma using the ratio of the fundamental frequency current and the second harmonic frequency current.

11. A device generating plasma including a plurality of probes with asymmetric areas comprising:
a chamber in which plasma is generated;
a plurality of probes disposed inside the chamber;
a voltage applicator that applies a preset voltage to the plurality of probes;
a current measuring part that measures current flowing through the plurality of probes;
a plasma analysis part that calculates the electron temperature and density of the plasma inside the chamber based on the results measured by the current measuring part, and
wherein the plurality of probes each have an area of different size.

12. A method of measuring plasma state variable using a dual probe with asymmetric area comprising:
a voltage application step of applying a preset voltage to a first probe and a second probe having different areas each and disposed inside a chamber;
a current measuring step of measuring current flowing through the first probe and the second probe; and
a plasma analysis step of calculating the electron temperature and density of the plasma inside the chamber based on the results measured in the current measuring step.

13. The method of measuring plasma state variable using a dual probe with asymmetric area according to claim 12,
wherein the first probe and the second probe have the same shape and the area of the first probe is larger than that the area of the second probe.

14. The method of measuring plasma state variable using a dual probe with asymmetric area according to claim 13,
wherein the plasma analysis step includes a step of calculating the electron temperature and density of the plasma using the relationship between the measured value of the current and area ratio information for the second probe based on the first probe, area information of the first probe, density information of the current, and information on the magnitude of the voltage.

15. The method of measuring plasma state variable using a dual probe with asymmetric area according to claim 14,
wherein the plasma analysis step includes a step of calculating the electron temperature and density of plasma using the relative size information of the fundamental frequency current and the harmonic frequency current after classifying the measured current as the sum of the fundamental frequency current and harmonic frequency currents having a frequency that is an integer multiple of the frequency of the fundamental frequency current.
